(19) United States
(12) Patent Application Publication
(10) Pub. No.: US 2024/0343157 A1
(43) Pub. Date: Oct. 17, 2024

(54) VEHICLE RANGE ESTIMATOR

(71) Applicant: Cummins Inc., Columbus, IN (US)

(72) Inventors: Martin T. Books, Columbus, IN (US); Richard A. Booth, Columbus, IN (US)

(21) Appl. No.: 18/752,444

(22) Filed: Jun. 24, 2024

Related U.S. Application Data
(63) Continuation of application No. 17/273,300, filed on Mar. 3, 2021, now abandoned.
(60) Provisional application No. 62/773,691, filed on Nov. 30, 2018.

(51) Int. Cl. B60L 58/12; B60K 6/46; G01R 31/382

(52) U.S. Cl. CPC B60L 58/12; B60K 6/46; G01R 31/382; B60L 2260/52; B60L 2260/54

(57) ABSTRACT

The present disclosure provides a method for determining the range of an electric vehicle or a hybrid electric vehicle. The method determines the range by estimating a SOC of the vehicle battery and/or a fuel gain by segregating estimation events and weight averaging data samples based on distance traveled during a sample period. The present disclosure also provides a method for determining battery failure for vehicles.

### CROSS-REFERENCE TO RELATED PATENT APPLICATIONS

This application is a continuation of and claims priority to U.S. Ser. No. 17/273,300, filed Mar. 3, 2021, which claims priority to and is a national phase filing of International Application No. PCT/US2019/063760, filed Nov. 27, 2019, which claims reference to U.S. Provisional Application No. 62/773,691, filed Nov. 30, 2018, the disclosures of which being expressly incorporated herein by reference.

### TECHNICAL FIELD OF THE PRESENT DISCLOSURE

The present invention generally relates to a method for determining the range of a vehicle, and more particularly, to a method to determine the state-of-charge (SOC) gain and fuel gain for determining the range for an electric vehicle.

### BACKGROUND OF THE PRESENT DISCLOSURE

Passenger cars can keep track of the remaining fuel/energy in a vehicle. In some cases, passenger vehicles use this information in route planning where based on the fuel/energy remaining in the passenger vehicle and a destination input, the vehicle plans the best route for the vehicle to travel. In some cases, the fuel/energy consumption characteristics in the vehicle can be used in fuel/energy forecasting where the vehicle determines how much fuel is needed to reach a destination.

### SUMMARY OF THE PRESENT DISCLOSURE

The present disclosure provides a method for determining the range of an electric vehicle or a hybrid electric vehicle. The method determines the range by estimating a state of charge (SOC) of the vehicle battery and/or a fuel gain by segregating estimation events and weight averaging data samples based on distance traveled during a sample period. The present disclosure also provides a method for determining battery failure for vehicles.

According to an exemplary embodiment of the present disclosure, a method of estimating a range of a vehicle is disclosed. The method comprises determining a state of charge (SOC) gain by detecting a beginning of a first sampling period, the first sampling period being an SOC sampling period, accumulating data representing a vehicle distance travelled during the SOC sampling period, and processing data at the end of the sampling period, wherein processing data includes calculating an instantaneous SOC gain. The method also comprises calculating an average SOC gain; beginning a second sampling period, the second sampling period being a fuel sampling period; and determining a fuel gain by detecting the beginning of the fuel sampling period, accumulating data representing a second vehicle distance travelled during the fuel sampling period, and processing data at the end of the fuel sampling period, wherein the end of the fuel sampling period is the beginning of a second SOC sampling period. The method also comprises calculating a current vehicle range using at least one of the average fuel gain and the average SOC gain, wherein the average fuel gain and the average SOC gain are weighted averages based on the vehicle distance during sampling periods, and notifying a vehicle operator of the current vehicle range.

The beginning of either the first sampling period or the second sampling period may be determined by at least one of: an ending of another sampling period; a system power-up established by manipulation of a vehicle key-switch; operation of a range extender; and a battery charging event. The end of either the first sampling period or the second sampling period may be determined by a predetermined time threshold or a predetermined distance threshold. The step of processing data may include calculating an assumed SOC distance, calculating an assumed fuel distance, calculating an instantaneous fuel gain during the fuel sampling period, and calculating an average fuel gain during the fuel sampling period.

The step of calculating the instantaneous SOC gain may include using the vehicle distance travelled during the SOC sampling period. The stop of calculating the average SOC gain may include using the instantaneous SOC gain and the vehicle distance travelled during the SOC sampling period, an average SOC gain from a previous SOC sampling period, and a cumulative total vehicle distance travelled during SOC sampling periods. The step of calculating the assumed SOC distance may include using the average SOC gain and a change in SOC during the fuel sampling period. The step of calculating the assumed fuel distance may include using a vehicle distance measured in the fuel sampling period and the assumed SOC distance for the fuel sampling period. The step of calculating an instantaneous fuel gain may include using the assumed fuel distance. The step of calculating the average fuel gain may include using the instantaneous fuel gain, assumed fuel distance during the fuel sampling period, an average fuel gain from a previous fuel sampling period, and a cumulative total vehicle distance travelled during fuel sampling period. The step of calculating the current vehicle range may include using the average SOC gain and the average fuel gain.

The steps of calculating an average SOC gain and calculating an average fuel gain may include using stored gain factors for repeated routes travelled by the vehicle.

In another exemplary embodiment of the present disclosure, a method of estimating a range of a vehicle is disclosed. The method comprises determining a state of charge (SOC) gain by detecting a beginning of a first sampling period, the first sampling period being an SOC sampling period; accumulating data representing a vehicle distance travelled during the SOC sampling period; and processing data a the end of the sampling period, wherein processing data includes calculating an instantaneous SOC gain, calculating an average SOC gain, wherein the average SOC gain is a weighted average based on the vehicle distance during SOC sampling periods, and a calculating a current vehicle range. The method also comprises beginning a second sampling period and notifying a vehicle operator of the current vehicle range.

The end of either the first sampling period or the second sampling period may be determined by a predetermined time threshold or a predetermined distance threshold. The second sampling period may be one of an SOC sampling period or a fuel sampling period determined by operation of a range extender. The beginning of either the first sampling period or the second sampling period may be determined by at least one of: an ending of another sampling period; a system power-up established by manipulation of a vehicle key-switch; operation of a range extender; and a battery charging event.

The step of accumulating data may include monitoring battery charging events. The step of calculating the instantaneous SOC gain may include using the vehicle distance during the SOC sampling period. The step of calculating the average SOC gain may include using the instantaneous SOC gain and the vehicle distance during the SOC sampling period, an average SOC gain from a previous SOC sampling period, and a cumulative total vehicle distance travelled during SOC sampling periods. The step of calculating the current vehicle range includes using the average SOC gain.

In yet another exemplary embodiment of the present disclosure, a method for calculating a battery failure metric is disclosed. The method comprises calculating an average SOC gain from a previous SOC sampling period; calculating an adjusted average SOC gain by applying an adjustment factor to the average SOC gain, wherein the adjustment factor is calculated from a current number of online batteries operated during a current SOC sampling period and from a number of online batteries operated during the previous SOC sampling period; applying the adjusted average SOC gain to calculate a vehicle range; and notifying the operator of the vehicle range.

Additional features and advantages of the present disclosure will become apparent to those skilled in the art upon consideration of the following detailed description of the illustrative embodiments exemplifying the disclosure as presently perceived.

### BRIEF DESCRIPTION OF THE DRAWINGS

The detailed description of the drawings particularly refers to the accompanying figures in which:

FIG. 1 is a schematic block diagram of a hybrid vehicle system;

FIG. 2 provides a flowchart illustrating a method in accordance with the present disclosure;

FIG. 3 is a graph illustrating simulation results measuring state of charge (SOC) estimation for a battery powered electric vehicle (BEV);

FIG. 4 is a graph expanding a portion of the graph of FIG. 3 by limiting the cumulative distance travelled by the BEV to the first 2,000 km travelled;

FIG. 5 is a graph illustrating the ability of a method of the present disclosure to track the degradation trajectory of the battery of the BEV;

FIG. 6 is a graph illustrating the ability of a method of the present disclosure to track cyclic variation in the battery life of the BEV;

FIG. 7 is a graph illustrating simulation results for measuring an SOC gain estimate in relation to a theoretical SOC gain estimate of a BEV;

FIG. 8 is a graph expanding a portion of the graph of FIG. 7 by limiting the distance travelled by the BEV to the first 2,000 km;

FIG. 9 is a graph illustrating the sampling periods of a method of the present disclosure for a range extended electric vehicle (REEV);

FIG. 10 is a graph illustrating simulation results measuring state of charge gain estimation for the REEV;

FIG. 11 is a graph expanding a portion of the graph of FIG. 10 by limiting the cumulative distance travelled by the REEV to the first 2,000 km;

FIG. 12 is a graph illustrating simulation results measuring a fuel gain estimation for the REEV;

FIG. 13 is a graph expanding a portion of the graph of FIG. 12 by limiting the cumulative distance travelled by the REEV to the first 2,000 km;

FIG. 14 is a graph illustrating the ability of a method of the present disclosure to track cyclic variation in the SOC gain of the REEV;

FIG. 15 is a graph illustrating the ability of a method of the present disclosure to track cyclic variation in the fuel gain of the REEV;

FIG. 16 is a graph illustrating simulation results for measuring the SOC gain estimate in relation to a theoretical SOC gain estimate of a REEV;

FIG. 17 is a graph expanding a portion of the graph of FIG. 16 by limiting the distance travelled by the REEV to the first 2,000 km;

FIG. 18 is a graph illustrating simulation results for measuring the fuel gain estimate in relation to a theoretical fuel gain estimate of the REEV;

FIG. 19 is a graph expanding a portion of the graph of FIG. 18 by limiting the cumulative distance to the first 2,000 km; and

FIG. 20 provides a flowchart illustrating a method in accordance with the present disclosure;

FIG. 21 is a graph illustrating simulation results for measuring the SOC gain estimate in relation to a theoretical SOC gain estimate of a REEV based on REEV operation on a single route; and

FIG. 22 is a graph illustrating simulation results for measuring the SOC gain estimate in relation to a theoretical SOC gain estimate of a REEV based on REEV operation having daily routes that can vary.

Corresponding reference characters indicate corresponding parts throughout the several views. Although the drawings represent embodiments of various features and components according to the present disclosure, the drawings are not necessarily to scale and certain features may be exaggerated in order to better illustrate and explain the present disclosure. The exemplification set out herein illustrates an embodiment of the invention, and such an exemplification is not to be construed as limiting the scope of the invention in any manner.

### DETAILED DESCRIPTION OF THE DRAWINGS

The present disclosure provides a method for determining the range of an electric vehicle or a hybrid electric vehicle. The method determines the range by estimating a state of charge (SOC) of a battery of the vehicle and/or a fuel gain by segregating estimation events and weight averaging data samples based on distance traveled during a sample period. The present disclosure also provides a method for determining battery failure for vehicles.

As discussed further herein, the present disclosure provides a method for calculating a vehicle driving range estimate for various vehicle types. The present disclosure discloses embodiments for a battery electric vehicle (BEV) and a range extended electric vehicle (REEV), also known as a series hybrid. However, it is within the scope of the present disclosure that the method described herein can be applied to other vehicle types, such as conventional gasoline, diesel, or natural gas-powered vehicles.

The methods discussed herein serve to establish a relationship between a vehicle travel distance and consumption of stored energy through a variety of vehicle relationship factors. Exemplary vehicle relationship factors include: battery SOC %, battery energy (kW-h or joules), fuel volumetric consumption (gallons or liters), fuel mass consumption (kg), and fuel energy consumption (kW-h or joules). These relationship factors are converted into “gain” factors, which function to convert the remaining stored energy to distance potential for the vehicle as described further herein. The methods of the present disclosure also serve to account for vehicle differences and day-to-day differences in various factors such as: route difficulty (stops, speed, variability, terrain, etc.), driver behavior, accessory loading (may cycle daily and seasonally), etc.

As further described herein, the method used for establishing energy to distance “gain” factors include empirically deriving all the necessary vehicle information to calculate the gain factors. More specifically, empirically deriving vehicle information includes: working in SOC, liters of fuel, and measured distance domains. Empirical derivation also includes at a designated event, recording distance since the last designated event and SOC change since the last designated event. In addition, as discussed further herein, the empirically derived gain factor is determined by dividing the change in distance by the change of SOC. Moreover, the method described herein automatically accounts for all energy usage factors (e.g., accessory loads such as power steering, cooling pumps and fans, HVAC, pneumatics, etc.) without having to separate them. For REEVs, the method for determining gain as discussed further herein includes first estimating SOC gain and then using the estimated SOC gain to estimate fuel gain. Results from the method can be aggregated into a filtered value that allows the calculated gains to change as needed, but still remain stable for the short term.

The disclosure below discusses methods of calculating gain characteristics for various types of vehicles (e.g., BEV and REEV), and from the gain characteristics, estimating a distance range for the vehicle. However, as mentioned previously, it is within the scope of the present disclosure that the methods described herein can be applied to other vehicle types, such as conventional gasoline, diesel, or natural gas-powered vehicles.

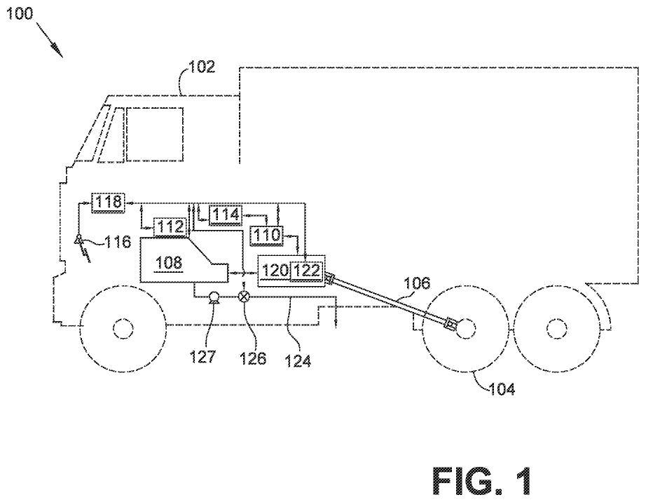

Referring first to FIG. 1, an exemplary system 100 includes a vehicle 102 that includes cargo carrying capability, although the system 100 is not limited to cargo carrying vehicles. For example, the system 100 may also be used in conjunction with passenger vehicles, transit vehicles, and other vehicles. The system 100 further includes a hybrid power train having an internal combustion engine 108 and an electric device 110 selectively coupled to a drive shaft 106. The engine 108 may be any type of internal combustion engine known in the art. In some applications, the internal combustion engine 108 may be a diesel engine. In the example of FIG. 1, the engine 108 and the electric device 110 are coupled to the driveshaft 106 through a transmission 120 having a power splitter (not shown). However, any hybrid configuration known in the art, including at least series, parallel, and series-parallel, is contemplated herein.

The system 100 further includes an electric generator that is selectively coupled to the drive shaft 106 and further coupled to an electrical energy storage device 114. The electric generator in FIG. 1 is included with the electric device 110 as an electric motor/generator. However, the electric generator may be a separate device. The electrical energy storage device 114 is electrically connected to the generator of the electric device 110 to store electricity generated by the generator. The electrical energy storage device 114 can be a battery such as a lithium ion battery, a lead-acid battery, a nickel metal hydride battery, or any other device capable of storing electrical energy. In certain embodiments, energy may be stored non-electrically, for example in a high performance fly wheel, in a compressed air tank, and/or through deflection of a high capacity spring. Where the energy is stored electrically, any electrical energy storage device 114 is contemplated herein, including a hyper-capacitor and/or an ultra-capacitor. The electric generator may be coupled to the internal combustion engine 108 to comprise a range extender as discussed further herein.

In certain embodiments, the system 100 includes the drive shaft 106 mechanically coupling the hybrid power train to a vehicle drive wheel 104. The system 100 may include any type of load other than or in addition to the drive wheel 104, for example any load that includes stored kinetic energy that may intermittently be slowed by any braking device included in the hybrid power train.

An exemplary mechanical braking device includes a compression braking device 112, for example a device that adjusts the valve timing of the engine 108 such that the engine becomes a torque absorber rather than a torque producer. Another exemplary mechanical braking device includes an exhaust throttle 126 (or exhaust brake) that, in moving toward a closed position, partially blocks an exhaust stream 124 and applies back pressure on the engine resulting in a negative crankshaft torque amount. Yet another exemplary mechanical braking device is a variable geometry turbocharger (VGT) 127. Certain VGT 127 devices can be adjusted to produce back pressure on the engine 108 and provide a braking effect. Still another exemplary mechanical braking device includes a hydraulic retarder 122.

The system 100 further includes a deceleration request device 116 that provides a deceleration request value. An exemplary deceleration request device 116 comprises a throttle pedal position sensor. However, any device understood in the art to provide a deceleration request value, or a value that can be correlated to a present negative torque request for the hybrid power train is contemplated herein.

The system 100 further includes a controller 118 having modules structured to functionally execute operations for managing start/stop operation of engine 108. In certain embodiments, the controller 118 forms a portion of a processing subsystem including one or more computing devices having memory, processing, and communication hardware. The controller 118 may be a single device or a distributed device, and the functions of the controller 118 may be performed by hardware or software.

In certain embodiments, the controller 118 includes one or more modules structured to functionally execute the operations of the controller 118. In certain embodiments, the controller 118 may include one or more of a first engine restart module that sets the restart frequency and duration of the engine 108 in response to a sensed ambient temperature, a second engine restart module that controls the running of the engine 108 in response to a sensed characteristic temperature associated with the engine 108, a third engine restart module that controls the running of the engine 108 in response to occurrence or non-occurrence of expected charging events along a predefined route, a fourth engine restart module that controls the running of the engine 108 in response to a state-of-charge of the energy storage device 114, and a route optimization module that sets and adjusts a proposed route to a destination that will result in reduced engine usage.

The description herein including modules emphasizes the structural independence of the aspects of the controller 118 and illustrates one grouping of operations and responsibilities of the controller 118. Other groupings that execute similar overall operations are understood within the scope of the present application. Modules may be implemented in hardware and/or software on computer readable medium, and modules may be distributed across various hardware or software components. Additionally, the controller 118 need not include all of the modules discussed above.

Certain operations described herein include evaluating one or more parameters. Evaluating, as utilized herein, includes, but is not limited to, receiving values by any method known in the art, including at least receiving values from a datalink or network communication, receiving an electronic signal (e.g., a voltage, frequency, current, or PWM signal) indicative of the value, receiving a software parameter indicative of the value, reading the value from a memory location on a computer readable medium, receiving the value as a run-time parameter by any means known in the art, and/or by receiving a value by which the interpreted parameter can be calculated, and/or by referencing a default value that is interpreted to be the parameter value.

### 1. Battery Electric Vehicle (BEV)

In a BEV, the method described herein is used to estimate and report available vehicle driving range based on current remaining battery charge.

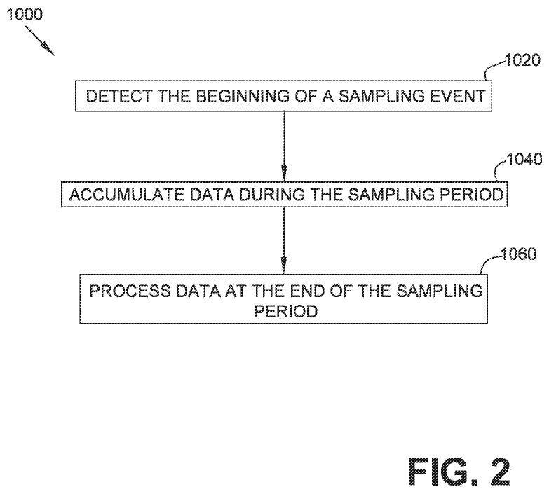

Referring to FIG. 2, a general method 1000 to calculate gain characteristics and in turn, estimate the vehicle range is provided. In one embodiment, an electronic control module (not shown) performs the method 1000 to calculate the gain characteristics.

As shown, the method 1000 begins at block 1020 where a beginning of a sampling event is detected. Detection of the beginning of the sampling event differentiates between samples and is based on a triggering event. For a BEV, a battery charging event may be the triggering event that marks the beginning of a sampling event. In one embodiment, the end of the charging event (i.e., when the battery is fully charged-100% SOC) is the triggering event and the beginning of the sampling event. If the battery is not fully charged, then a sampling event is not detected and the prior sample is continued. In an alternate embodiment, the beginning of a charging event is the triggering event and the beginning of the sampling event. In another embodiment, the beginning of the sampling event may be triggered by a system power-up established by the vehicle key-switch being turned on. In yet another embodiment, the sampling event may simply be the passage of time or distance where a maximum sample size is enforced and, once reached, a new sample event is triggered. In an alternate embodiment, a threshold may be applied to the sampling process. That is, a minimum amount of data may need to be recorded to generate a valid sample. In this embodiment, if the sample period is shorter than the threshold, the method 1000 may either discard the data and not include it in the subsequent gain calculations or save the data recorded and append it to the beginning of the next sample.

When beginning a new sampling event (i.e., the beginning of the new sampling event is detected), data generated during the previous sampling event should be processed to generate a gain estimate. The gain estimate considers total distance travelled during the sampling event and the cumulative change in SOC, including any increase in SOC due to external charging over the sample period, which may include multiple charges if the battery was not fully charged as discussed above.

After the beginning of the sampling period is detected, data is accumulated during the sampling period as indicated by block 1040. One characteristic that is measured and accumulated is the distance travelled by the vehicle during the sampling period. This metric can be determined and recorded by either integrating the vehicle speed during the sampling period or through the use of an already existing calculation. Another characteristic that is monitored during the sampling period is battery charging events to detect a new sampling event. In addition, if any charging events occur that do not fully recharge the battery, an accounting of the SOC increase from the charging event is recorded and maintained. Similarly, if multiple charging events occur without achieving a full charge, the cumulative SOC increase for all charging during the sampling period is recorded.

When the next sampling event is detected (e.g., end of charging event), a new sampling period begins. Also, the current sampling period ends at the same instant, and data from the previous sampling period is processed at block 1060. In processing the data of the sampling period, an instantaneous SOC gain is calculated according to Equation 1 shown below.

$$\\ \begin{matrix}Instantaneous SOC Gain = \frac{total distance during sampling period}{\sum ( SOC changes during sampling period )} & Equation 1\end{matrix}$$

As shown, the instantaneous SOC gain is calculated by dividing the total travelled distance by the vehicle during the sampling period by the summation of SOC changes during the sampling period. The instantaneous SOC gain from Equation 1 is then used to calculate an average SOC gain from Equation 2 shown below:

$$\\ \begin{matrix}Average SOC Gain = \frac{( ISG \times SD ) + ( {ASG}_{z - 1} \times {TD}_{z - 1} )}{( SD + {TD}_{z - 1} )} & Equation 2\end{matrix}$$

where ISG is the instantaneous SOC Gain from Equation 1, SD is the total distance travelled during the sampling period, ASG_{z-1} is the average SOC gain from the accumulation of previous sampling periods, and TD_{z-1} is the cumulative total vehicle distance traveled from the previous samples. As shown in Equation 2, the average SOC gain is a weighted average based on the distance travelled for the current sampling period in light of the total cumulative distance travelled. Also, a maximum limit is applied to TD_{z-1} such that the weight of previous values from prior sampling periods does not become so large that any new samples are rendered insignificant. Applying a maximum limit to TD_{z-1} provides greater robustness to the average SOC gain calculation such that the average SOC gain can be accurate (i.e., track any real changes to the theoretical SOC gain) throughout the product's life and/or in different conditions (e.g., different seasonal conditions-spring, summer, fall, and winter).

After a value of the average SOC gain has been determined, an estimation of the remaining vehicle range can be determined by applying the average SOC gain with the current battery SOC according to Equation 3 shown below.

$$\\ \begin{matrix}Current Vehicle Range = Average\_SOC \_Gain \times Current\_SOC & Equation 3\end{matrix}$$

Once the vehicle range is calculated, the vehicle range is reported to the operator of the vehicle based on current remaining battery charge.

a. Simulation Studies-BEV

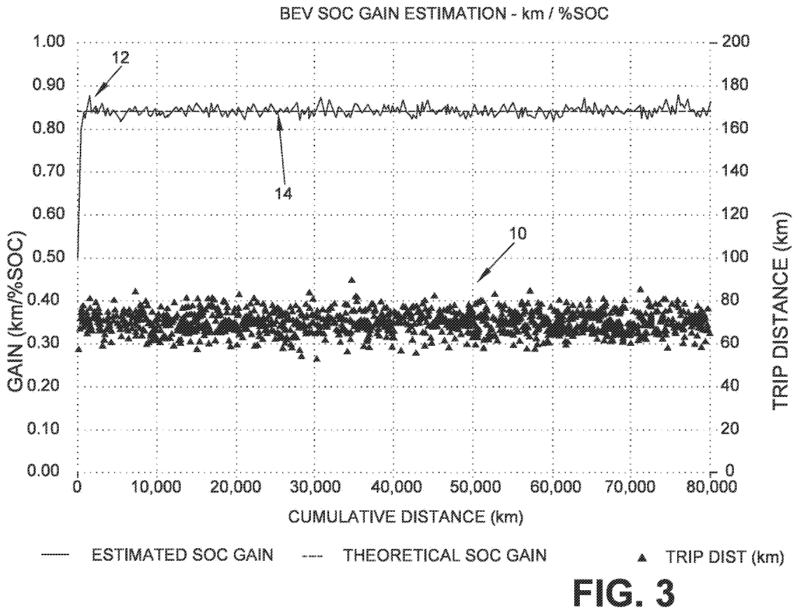

Simulation studies for a BEV were conducted and generated results shown in FIGS. 3-6. The simulation studies were conducted with the following characteristics shown in Table 1 below.

TABLE 1
Daily “Trip” or Mission Distance

| | |
|---|---|
| Nominally | 70 km distributed normally |
| Standard Deviation | 5 km |

Theoretical Energy per km (Vehicle Load Plus Accessories)

| | |
|---|---|
| Nominally | 1.4 kW-h/km distributed |
| | normally (1.0 veh, 0.4 ace) |
| Standard Deviation | 0.026 kW-h/km (0.025 veh, |
| | 0.001 ace) |

Theoretical Energy Efficiency

| | |
|---|---|
| Nominally | 0.85 distributed normally |
| Standard Deviation | 0.02 |

Gain Trends Tested
0.00001 kW-h accessory load increase per km
0.1 kW-h cyclic change at 2 cycles per year

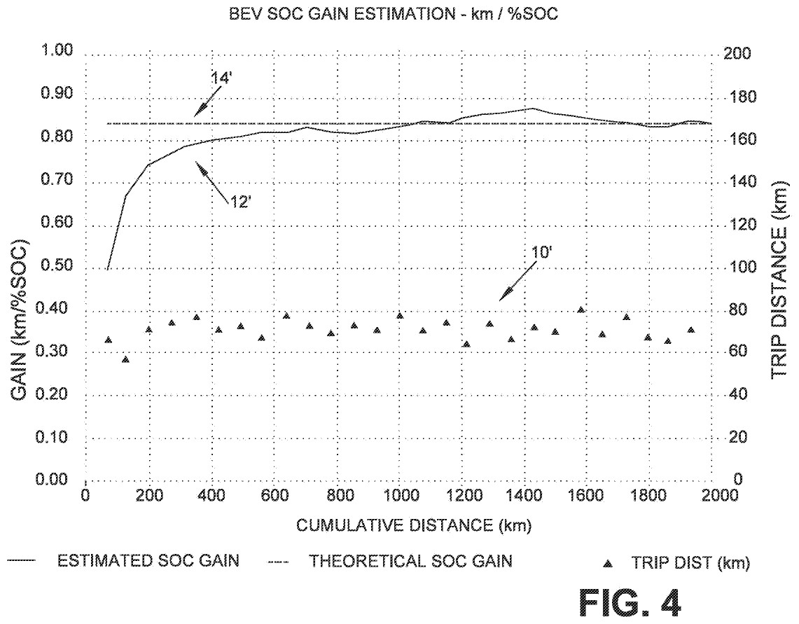

Referring to FIG. 3, a data set 10 provides a scatter plot of daily trip distances over a cumulative distance of 80,000 kilometers (km). As shown, the estimated SOC gain 12 calculated from the method described herein closely resembles the theoretical SOC gain 14. FIG. 4 shows an expanded view of the first 2,000 km demonstrating an average stabilization time. Similar to FIG. 3, a data set 10′ provides a scatter plot of daily trip distances over a cumulative distance of 2,000 km. As shown, when a gross under-estimated “seed” value of 40% below the theoretical SOC gain is used for the initial gain, the weighted average value reaches the theoretical mean value within under 600 km, or roughly 8 trips based on a trip estimate where a vehicle travels 80 km. That is, the estimated SOC gain 12′ calculated from the method described herein closely resembles the theoretical SOC gain 14′ in under 600 km, or roughly 8 trips based on a trip estimate where a vehicle travels 80 km.

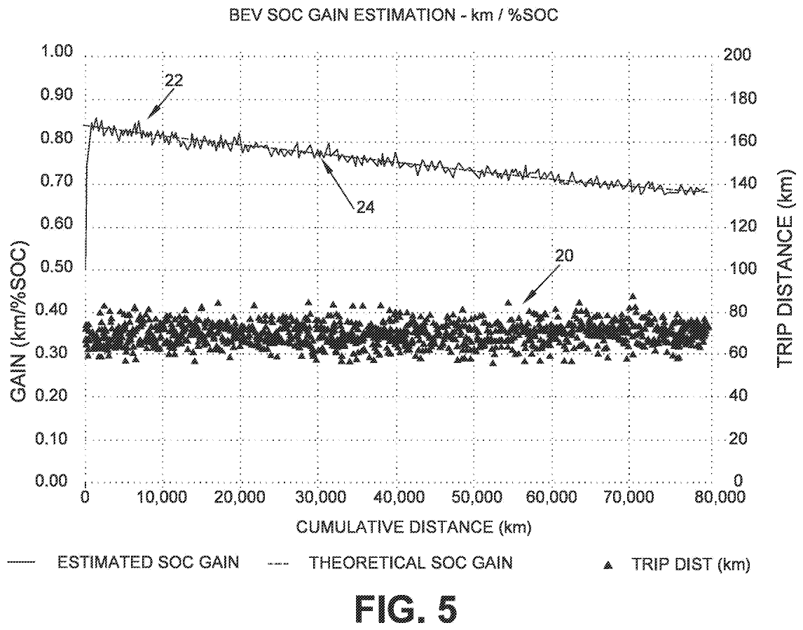

FIG. 5 shows the ability of the weighted average of the method described herein to track the degradation of the vehicle battery over its lifetime. Similar to FIGS. 3 and 4, data set 20 provides a scatter plot of daily trip distances over a cumulative distance of 80,000 km. As shown, the estimated SOC gain 22 calculated from the method described herein closely resembles the theoretical SOC gain 24 illustrating the degradation trajectory over the course of the battery's life.

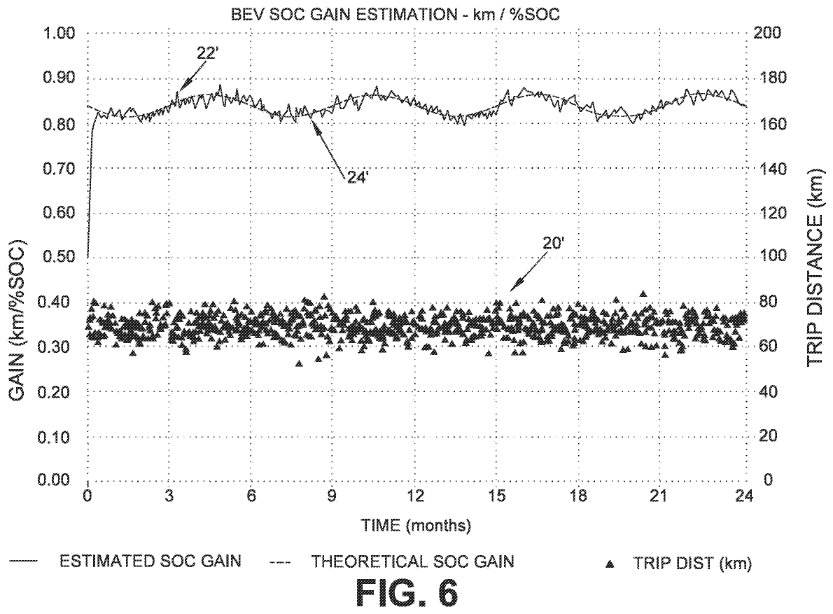

FIG. 6 shows the ability of the method described herein to track the cyclic variation of SOC in a BEV over the course of 24 months. Similar to FIGS. 3-5, data set 20′ provides a scatter plot of daily trip distances over time. As shown, the estimated SOC gain 22′ closely tracks the theoretical SOC gain 24′ over the 24 months.

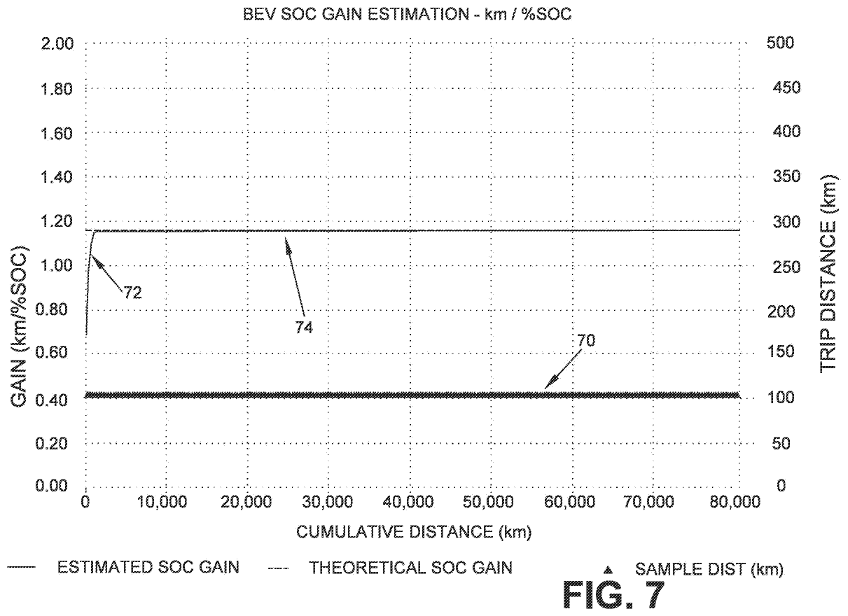

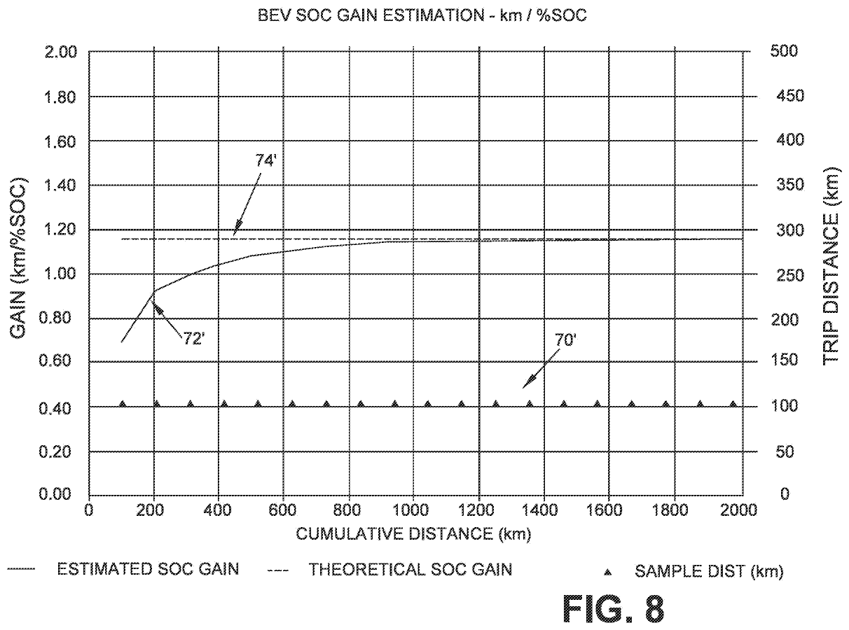

Referring now to FIGS. 7 and 8, the method described herein with respect to a BEV was applied using simulation data generated by a computer program. The data generated was for a single mission cycle (i.e., one day) and was insufficient to permit the method to fully converge on a solution. As a remedy, the data was appended end-to-end to produce a data set similar to the previous analysis shown in FIGS. 1-4.

Referring first to FIG. 7, a data set 70 provides a simulation data plot of daily trip distances over a cumulative distance of 80,000 km. As shown, the estimated SOC gain 72 calculated from the method described herein closely resembles the theoretical SOC gain 74. FIG. 8 shows an expanded view of the first 2,000 kilometers (km) demonstrating average stabilization time. Similar to FIG. 7, a data set 70′ of FIG. 8 provides a plot of daily trip distances over time. As shown, when a gross under-estimated “seed” value of 40% below the theoretical SOC gain is used, the weighted average value reaches the mean value over a greater period of time as compared with FIG. 4. That is, the estimated SOC gain 72′ calculated from the method described herein closely resembles the theoretical gain 74′ after approximately 800 km as compared to 600 km in the example of FIG. 4. However, this is due to the lack of scatter in the results (i.e., there is no “noise band” around the final mean value).

### 2. Range Extended Electric Vehicle (REEV)

The method described herein is used to estimate and report an available vehicle driving range based on current remaining battery charge and diesel fuel in a REEV. Also, the method described herein is used to estimate and report available vehicle driving range in a REEV if only electric driving were permitted.

For a REEV, there are two gains to be calculated to estimate the vehicle range-SOC gain and fuel gain.

Similar to a BEV and referring back to FIGS. 1 and 2, the method 1000 is used. As shown, method 1000 begins at block 1020 where a beginning of a sampling event is detected. Detection of the beginning of the sampling event differentiates between samples and is based on a triggering event. For a REEV, operation of the range extender (i.e. the combination of the internal combustion engine 108 and the generator) is the triggering event that marks the beginning of a sampling event. In particular, when the range extender is off, the system acts similarly to a BEV, and the method described above for a BEV can be used to estimate SOC gain. That is, turning the range extender off is the beginning of an SOC gain sampling event. When the range extender is on, fuel gain can be calculated as described herein using the previously estimated SOC gain. That is, turning the range extender on is the beginning of a fuel gain sampling event. In addition, if a battery charging event occurs, the end of the charging event is the beginning of a new sampling event, and the status of the range extender will identify which type of sample it is (SOC gain or fuel gain). In an alternate embodiment, similar to a BEV, a threshold may be applied to the sampling process. That is, a minimum amount of data may need to be recorded to generate a valid sample. In this embodiment, if the sample period is shorter than the threshold, the method 1000 may either discard the data and not include it in the subsequent gain calculations or save the data recorded and append it to the beginning of the next sample.

After the beginning of the sampling period is detected, data is accumulated during the sampling period as indicated by block 1040. One characteristic that is measured and accumulated is the distance travelled by the vehicle during the sampling period. This metric can be determined and recorded by either integrating the vehicle speed during the sampling period or through the use of an already existing calculation. For fuel gain estimation, the amount of fuel burned during the sampling period can be determined by electronic control module (ECM) data or the fuel tank level can be monitored by an external message.

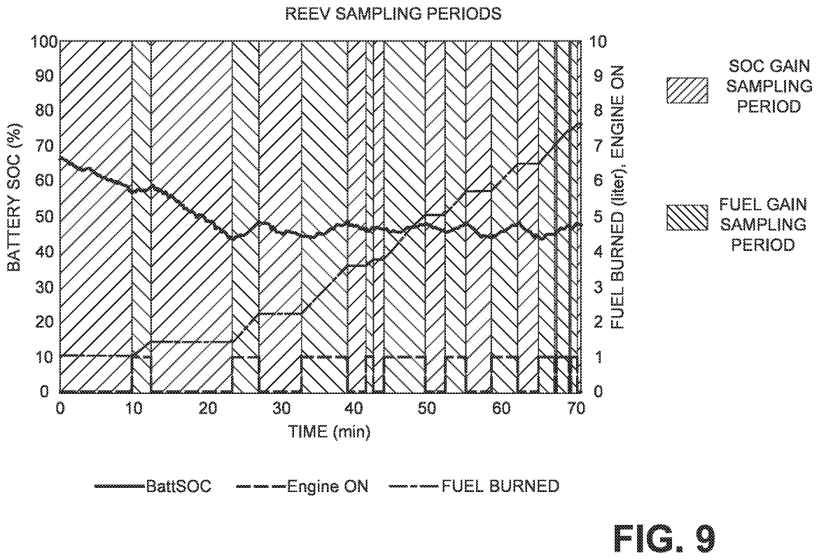

When the next sampling event is detected (e.g., range extender is turned on or off), a new sampling period begins, the current sampling period ends at the same instant, and data from the previous sampling period is processed at block 106. For a REEV, as shown in FIG. 9, the end of a SOC gain estimation is the beginning of a sampling period for a fuel gain estimation. Similarly, the end of a fuel gain estimation sampling period is the beginning of a sampling period for SOC gain estimation. To process the accumulated data in a REEV, an instantaneous SOC gain is calculated at the end of an SOC gain estimation period according to Equation 1 shown below.

$$\\ \begin{matrix}Instantaneous SOC Gain = \frac{total distance during sampling period}{\sum ( SOC changes during sampling period )} & Equation 1\end{matrix}$$

As shown, instantaneous SOC gain is calculated by dividing the total travelled distance by the vehicle during the sampling period by the summation of SOC changes during the sampling period. The instantaneous SOC gain from Equation 1 is then used to calculate average SOC gain from Equation 2 shown below:

$$\\ \begin{matrix}Average SOC Gain = \frac{( ISG \times SD ) + ( {ASG}_{z - 1} \times {TD}_{z - 1} )}{( SD + {TD}_{z - 1} )} & Equation 2\end{matrix}$$

where ISG is the instantaneous SOC gain from Equation 1, SD is the total distance travelled during the sampling period, ASG_{z-1} is the average SOC gain accumulation of from the previous sampling periods, and TD_{z-1} is the cumulative total vehicle distance traveled from the previous samples. As shown in Equation 2, average SOC gain is a weighted average based on the distance travelled for the current sampling period in light of the total cumulative distance travelled. Also, a maximum limit is applied to TD_{z-1} such that the weight of previous values from prior sampling periods does not become so large that any new samples are rendered insignificant. Applying a maximum limit to TD_{z-1} provides greater robustness to the average SOC gain calculation such that the average SOC gain can be accurate (i.e., track any real changes to the theoretical SOC gain) throughout the product's life and/or in different conditions (e.g., different seasonal conditions-spring, summer, fall, and winter).

Then, at the end of a fuel gain estimation sampling period, an instantaneous fuel gain is calculated. To calculate instantaneous fuel gain, the average SOC gain (from Equation 2) is used to determine the portion of the sample distance that can be attributed to the SOC change during the fuel sampling period using Equation 3 below.

$$\\ \begin{matrix}Assumed SOC Distance = Average SOC Gain \times ( SOC changes during sampling period ) & Equation 3\end{matrix}$$

Once the sample distance attributable to the measured SOC change is determined from Equation 3, the remaining sample distance is attributable to the fuel consumed and is calculated according to Equation 4 shown below.

$$\\ \begin{matrix}Assumed Fuel Distance = total distance during sampling period - Assumed SOC Distance & Equation 4\end{matrix}$$

The assumed fuel distance from Equation 4 is then used to calculate instantaneous fuel gain according to Equation 5 shown below.

$$\\ \begin{matrix}Instantaneous Fuel Gain = \frac{Assumed Fuel Distance}{Fuel changes during sampling period} & Equation 5\end{matrix}$$

As shown, instantaneous fuel gain is calculated by dividing the assumed fuel distance of Equation 4 by the fuel changes during the sampling period. The instantaneous fuel gain from Equation 5 is then used to calculate average fuel gain from Equation 6 shown below:

$$\\ \begin{matrix}Average Fuel Gain = \frac{( IFG \times AFD ) + ( {AFG}_{z - 1} \times {TFD}_{z - 1} )}{( AFD + {TFD}_{z - 1} )} & Equation 6\end{matrix}$$

where IFG is the instantaneous fuel gain from Equation 5, AFD is the assumed fuel distance from the sampling period, AFG_{z-1} is the average fuel gain from the accumulation of previous sampling periods, and TFD_{z-1} is the cumulative total vehicle distance traveled during the previous fuel samples. Similar to the average SOC gain of Equation 2, average fuel gain is a weighted average based on the distance travelled for the current sampling period in light of the total cumulative distance travelled. Also, a maximum limit is applied to TD_{z-1} such that the weight of previous values from prior sampling periods does not become so large that any new samples are rendered insignificant. Applying a maximum limit to TD_{z-1} provides greater robustness to the average fuel gain calculation such that the average fuel gain can be accurate (i.e., track any real changes to the theoretical fuel gain) throughout the product's life and/or in different conditions (e.g., different seasonal conditions-spring, summer, fall, and winter).

The average SOC gain and the average fuel gain are used with the current battery SOC and the current fuel tank level (i.e., remaining fuel in fuel tank) to estimate the range of the REEV.

$$\\ \begin{matrix}Current Vehicle Range = Average SOC Gain \times Current SOC + Average Fuel Gain \times Remaining Fuel & Equation 7\end{matrix}$$

Once the vehicle range is calculated, the vehicle range is reported to the operator of the vehicle based on current remaining battery charge and diesel fuel. If only electric driving is permitted, then the vehicle range is reported to the operator based on current remaining battery charge similar to a BEV.

a. Simulation Studies for REEV

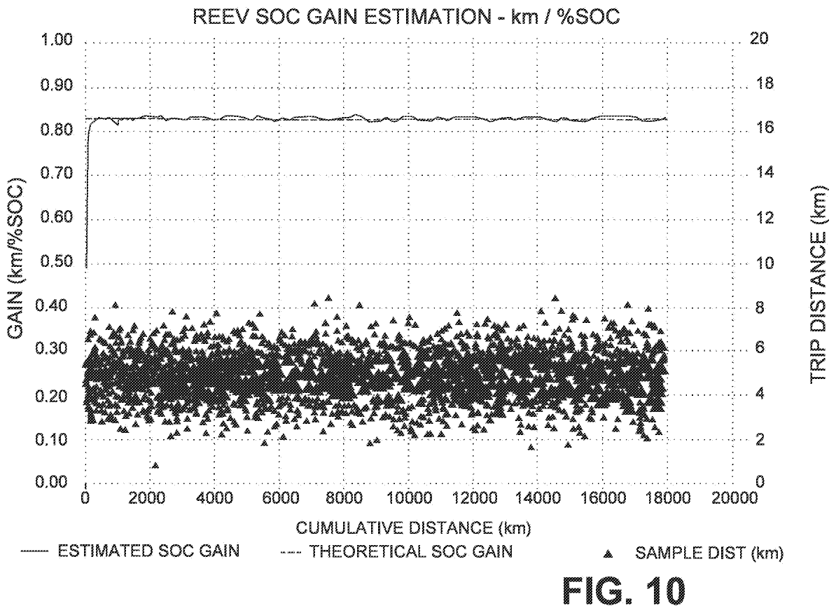

Simulation studies for REEV were carried out and generated results shown in FIGS. 10-15. The simulation studies were conducted with the following characteristics shown in Table 2 below.

TABLE 2
Sample Distance

| | |
|---|---|
| Nominally | 5 km distributed normally |
| Standard Deviation | 1 km |

Theoretical Energy per km (Vehicle Load Plus Accessories)

| | |
|---|---|
| Nominally | 1.4 kW-h/km distributed normally (1.0 |
| | veh, 0.4 ace) |
| Standard Deviation | 0.026 kW-h/km (0.025 veh, 0.001 ace) |

Theoretical Energy Efficiency

| | |
|---|---|
| Nominally | SOC: 85% distributed normally |
| | Fuel: 4.5 kW-h/liter distributed normally |
| Standard Deviation | SOC: 2% |
| | Fuel: 0.011 km/liter |

Gain Trends Tested
0.00001 kW-h accessory load increase per km
0.1 kW-h cyclic change at 2 cycles per year

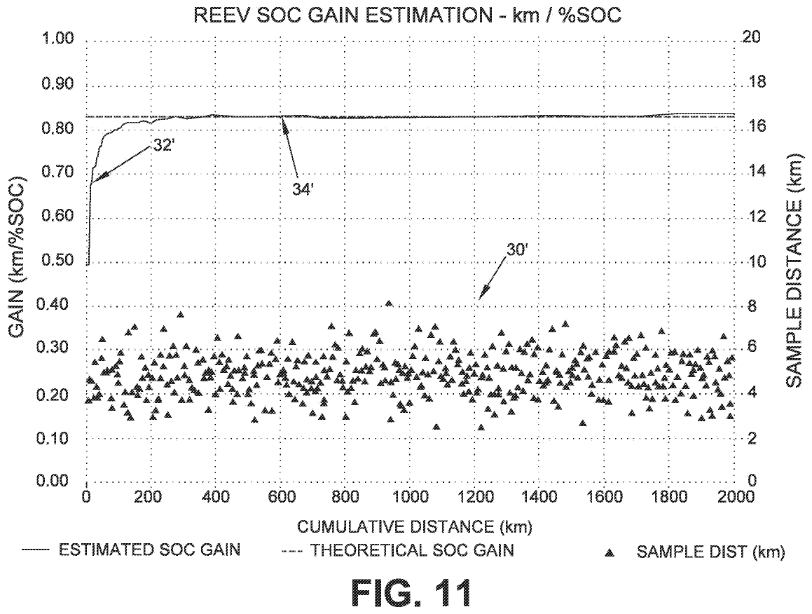

Referring to FIG. 10, a data set 30 provides a scatter plot of daily trip distances over a cumulative distance of 20,000 kilometers (km) and also provides the measures of the SOC gains. As shown, the estimated SOC gain 32 calculated from the method described herein closely resembles the theoretical SOC gain 34. FIG. 11 shows an expanded view of the first 2,000 km demonstrating average stabilization time. Similar to FIG. 10, a data set 30′ provides a scatter plot of daily trip distances over time. As shown, when a gross under-estimated “seed” value of 40% below the theoretical SOC gain is used, the weighted average value reaches the mean value within under 300 km, or roughly 4 trips based on a trip estimate where a vehicle travels 80 km. That is, the estimated SOC gain 32′ calculated from the method described herein closely resembles the theoretical SOC gain 34′ in under 300 km, or roughly 4 trips based on a trip estimate where a vehicle travels 80 km.

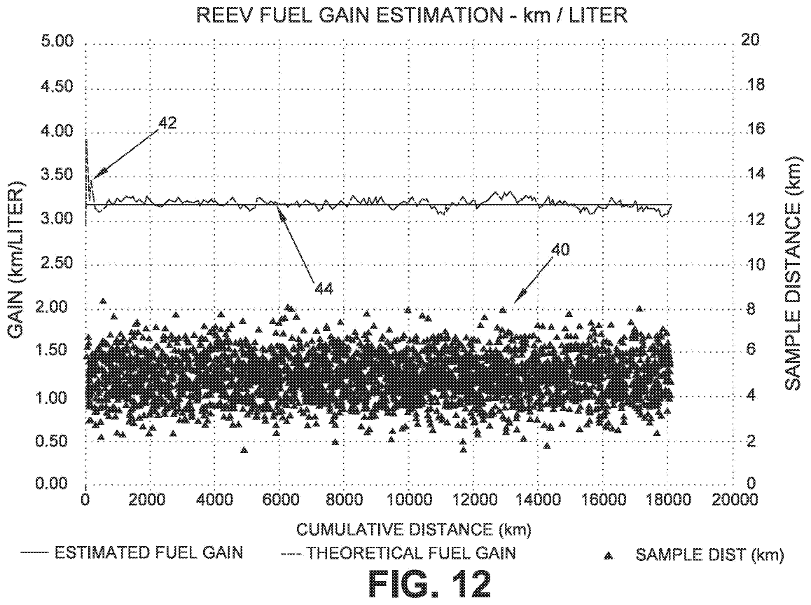

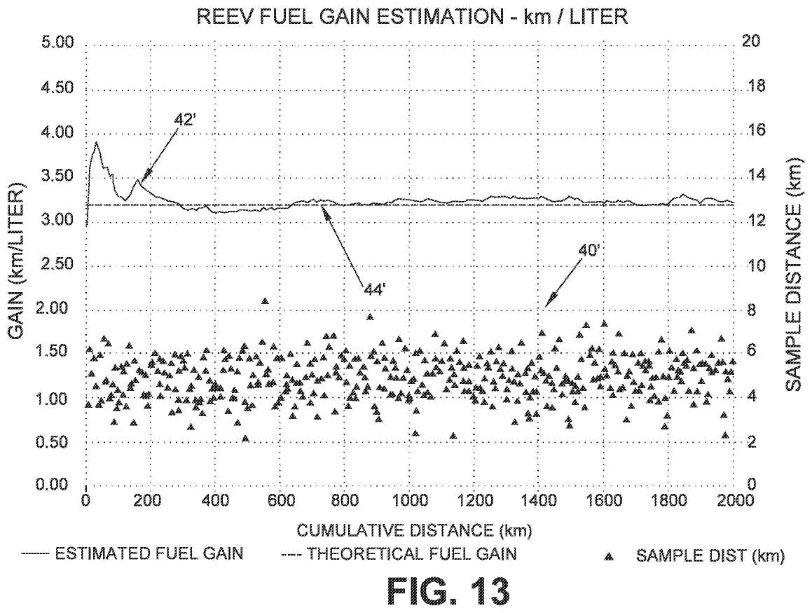

Similar to FIG. 10, a data set 40 of FIG. 12 provides a scatter plot of daily trip distances over a cumulative distance of 18,000 km and also provides the measures of the fuel gains. As shown, the estimated fuel gain 42 calculated from the method described herein closely resembles the theoretical SOC gain 44. FIG. 13 shows an expanded view of the first 2,000 kilometers (km) demonstrating average stabilization time. Similar to FIG. 12, a data set 40′ of FIG. 13 provides a scatter plot of daily trip distances over time. As shown, when a vehicle is faced with a gross under-estimated “seed” value of 40% below the theoretical fuel gain is used, the weighted average value reaches the mean value within under 400 km, or roughly 5 trips based on a trip estimate where a vehicle travels 80 km. That is, the estimated fuel gain 42′ calculated from the method described herein closely resembles the theoretical fuel gain 44′ in under 400 km, or roughly 5 trips based on a trip estimate where a vehicle travels 80 km.

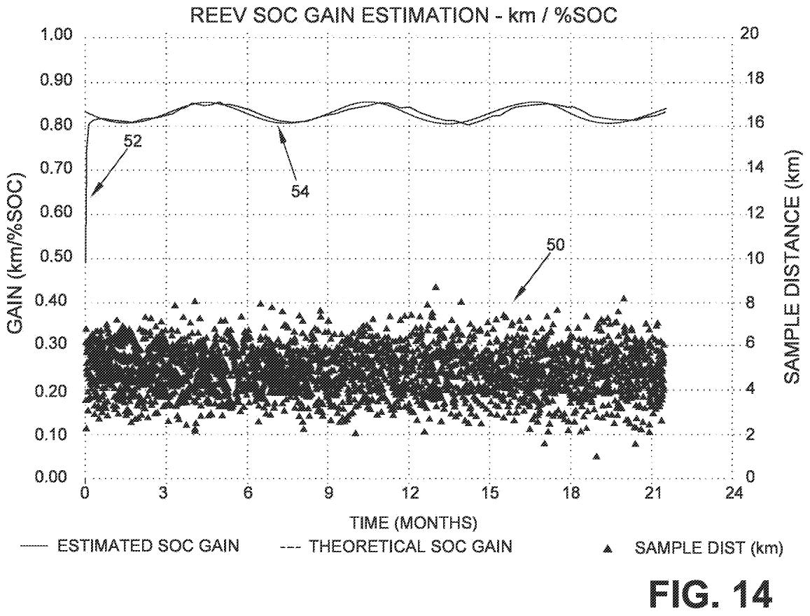

FIG. 14 shows the ability of the method described herein to track the cyclic variation of SOC in a REEV over the course of 21 months. Similar to FIGS. 10-13, a data set 50 provides a scatter plot of daily trip distances over time. As shown, the estimated SOC gain 52 closely tracks the theoretical SOC gain 54 over the 24 months.

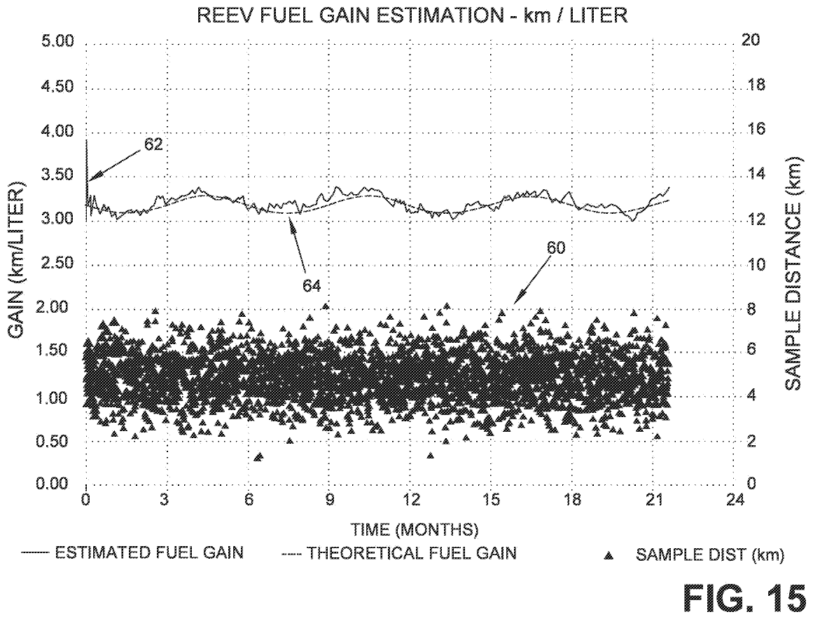

Similar to FIG. 14, FIG. 15 shows the ability of the method described herein to track the cyclic variation of fuel gain in a REEV vehicle over the course of 21 months. Similar to FIGS. 10-14, a data set 60 provides a scatter plot of daily trip distances over time. As shown, the estimated fuel gain 62 closely tracks the theoretical fuel gain 64 over the 24 months.

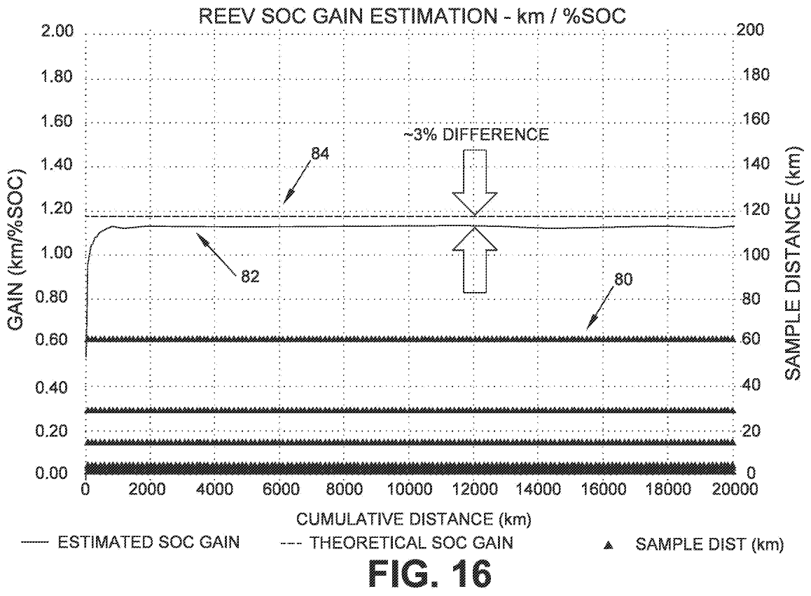

Referring now to FIGS. 16-19, the method described herein with respect to a REEV was applied using simulation data generated by a computer program. The data are presumed to be identical plant models and mission cycles as that of FIGS. 7 and 8 differing only in range extender usage. In addition, the data generated was of a single mission cycle (i.e., one day) and was insufficient to permit the method to fully converge on a solution. As a remedy, the data was appended end-to-end to produce a data set similar to the previous analysis shown in FIGS. 10-15.

Referring to FIG. 16, a data set 80 provides a simulation data plot of daily trip distances over a cumulative distance of 20,000 km. Also, the REEV method produces an SOC gain estimate of 1.16 km/% SOC, shown in FIG. 16 as the theoretical SOC gain 84. The REEV method shown as estimated SOC gain 82 converges on a value that is approximately 3% lower.

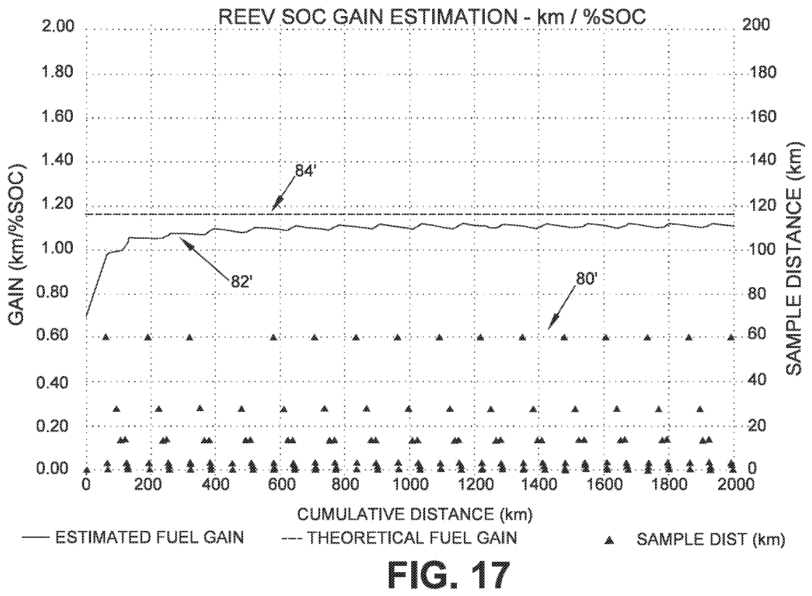

FIG. 17 shows an expanded view of the first 2,000 kilometers (km) demonstrating average stabilization time. Similar to FIG. 12, a data set 80′ of FIG. 17 provides a simulation data plot of daily trip distances over 2,000 km. As shown, when a vehicle is faced with a gross under-estimated “seed” value of 40% below the theoretical SOC gain is used, the weighted average value reaches the mean value within under 500 km, or roughly 7 trips based on a trip estimate where a vehicle travels 80 km. That is, the estimated SOC gain 82′ calculated from the method described herein closely resembles the theoretical SOC gain 84′ in under 500 km, or roughly 7 trips based on a trip estimate where a vehicle travels 80 km.

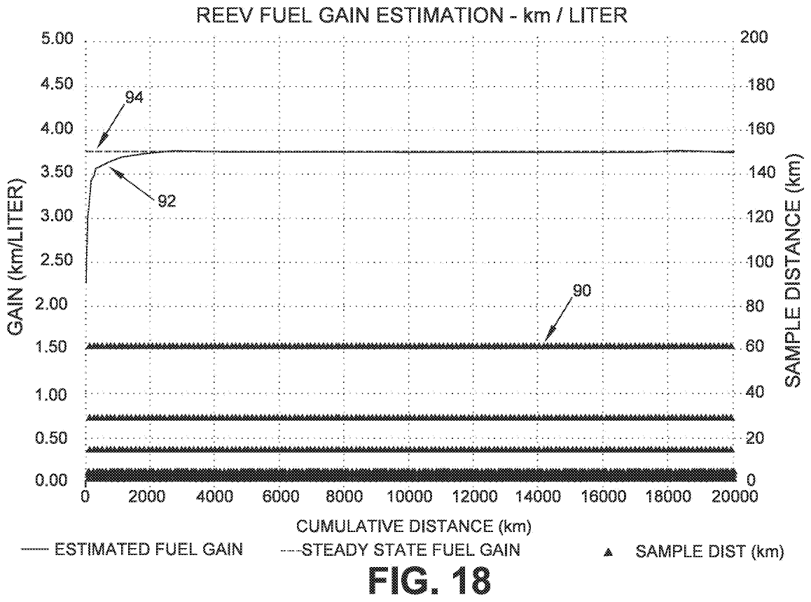

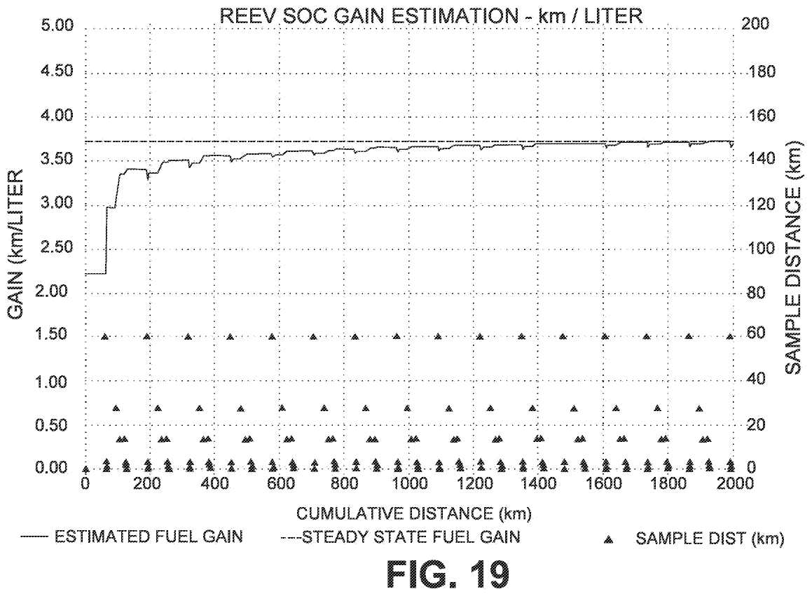

Referring now to FIG. 18, a data set 90 provides a simulation data plot of daily trip distances over a cumulative distance of 20,000 km. FIG. 18 also shows the settling time of estimated fuel gain 92 to steady state fuel gain estimate 94. FIG. 19 shows an expanded view of the first 2,000 km demonstrating average stabilization time. A data set 90′ of FIG. 19 provides a simulation data plot of daily trip distances over 2,000 km. As shown, when a vehicle is faced with a gross under-estimated “seed” value of 40% below the theoretical fuel gain is used, the weighted average value reaches the mean value (at a rate determined by engine usage in the vehicle, and averaging method calibration) at slightly more than 1000 km, or roughly 12 trips based on a trip estimate where a vehicle travels 80 km. That is, the estimated fuel gain 92′ calculated from the method described herein closely resembles the theoretical fuel gain 94′ at slightly more than 1000 km, or roughly 12 trips based on a trip estimate where a vehicle travels 80 km.

### 3. Range Estimation Utilizing Cloud Tallying

As disclosed herein, an average SOC gain factor and an average fuel gain factor are determined based on data accumulated during sampling periods. As discussed further herein, a method of estimating vehicle range is provided in which past historical data (gains calculated from the methods described herein (average fuel gain and average SOC gain)) is used as a predictor of future data. Such a method can be applied to homogenous data, i.e., for a vehicle that continuously repeats the same or similar routes (e.g., a bus).

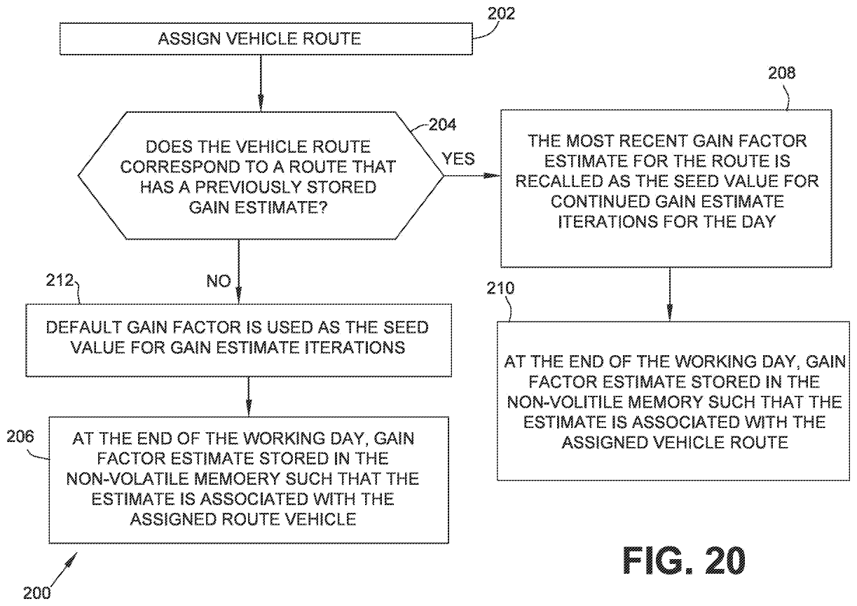

Referring now to FIG. 20, a method 200 is provided to measure and store gain estimates for a particular route. The method 200 begins at step 202 where at the beginning of each working day, an assigned vehicle route is identified. Once the vehicle route is assigned, the vehicle determines whether the assigned route corresponds to a route that has a previously stored gain estimate at step 204. If there is not a previously stored gain estimate, then at step 212 a default gain factor is used as the initial condition for iterative gain estimates. Then at step 206, the vehicle is operated and at the end of the working day, the updated gain factor estimate is stored in non-volatile memory in a manner uniquely and permanently associated with the assigned vehicle route. On subsequent days when the vehicle is assigned the same route, the estimation algorithm is seeded with this stored route-specific gain factor estimate and driving on this route during the day provides additional data for the gain factor estimate for the route. That is, data from the current day's run is used to calculate a new gain factor estimate for the route that will be used the next time a vehicle runs the route. This enables the maturity of the estimate for that route to continue free from the “noise” of other route assignments. Similarly, if a different vehicle route is assigned on subsequent days, a gain factor estimate for that assigned different route is recalled and used by the estimation algorithm as the seed value for that day, and the data accumulated by the vehicle during the day is combined with the previously stored data to calculate a new gain factor estimate that is used for the next run by a vehicle, thereby furthering the estimate maturity for that assigned different route.

Returning to step 204, if there is a previously stored gain estimate, then at step 208, the most recent/latest gain factor estimate for that particular route is recalled as the “seed” value for continued estimate iterations that day. The vehicle is then operated at step 210 and at the end of the working day, the gain factor estimate is stored in non-volatile memory in a manner uniquely and permanently associated with the assigned vehicle route. On subsequent days when the vehicle is assigned the same route, the estimation algorithm is seeded with this stored route-specific gain factor estimate and driving on this route during the day provides additional data for the gain factor estimate for the route. That is, data from the current day's run is used to calculate a new gain factor estimate for the route that will be used the next time a vehicle runs the route. This enables the maturity of the estimate for that route to continue free from the “noise” of other route assignments. Similarly, if a different vehicle route is assigned on subsequent days, a gain factor estimate for that assigned different route is recalled and used by the estimation algorithm as the seed value for that day, and the data accumulated by the vehicle during the day is combined with the previously stored data to calculate a new gain factor estimate that is used for the next run by a vehicle, thereby furthering the estimate maturity for that assigned different route

The route identification and gain factor estimate storage described in FIG. 20 can be offline and accessible by multiple vehicles (such as a remote storage (e.g., cloud storage) or any remotely accessed location) such that an entire fleet of vehicles can contribute to the maturation of a set of estimates for all vehicle routes. Each day, all vehicles are seeded with the appropriate gain factor estimate corresponding to their assigned routes. The vehicle activity for the associated route during that day will continue the gain factor estimate maturation of each assigned route as data for that respective route will be added to the previously stored data for that route and a further seed gain factor can be calculated. The further seed gain factor is then used for the next vehicle that runs the associated route. Such an iterative process can provide robust calculations of gain factors that closely resemble the theoretical gain factors as described herein. In turn, this leads to accurate vehicle range estimation, which is based on the calculated gain factors.

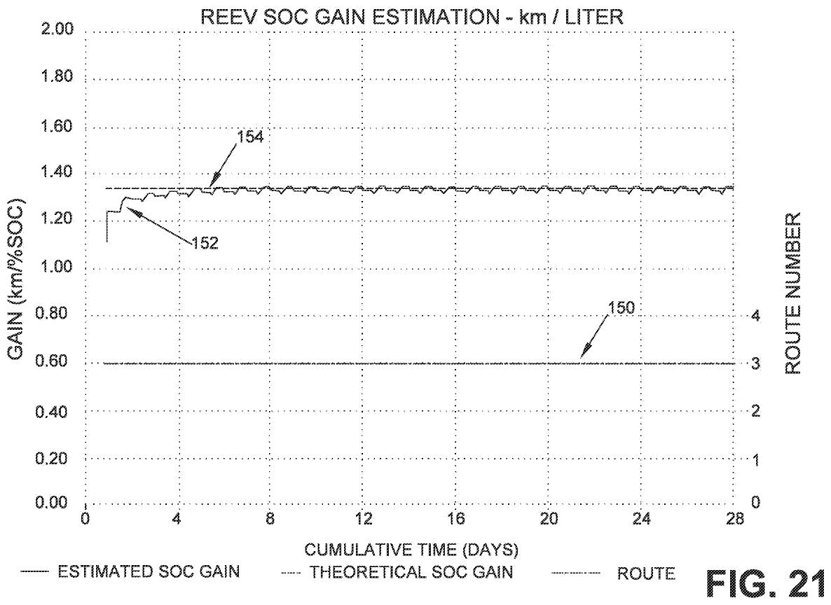

As shown in the simulation results of FIG. 21, for a vehicle that runs on route 3 for 28 months, the estimated SOC gain curve 152 converges on the theoretical SOC gain curve 154 after around four days.

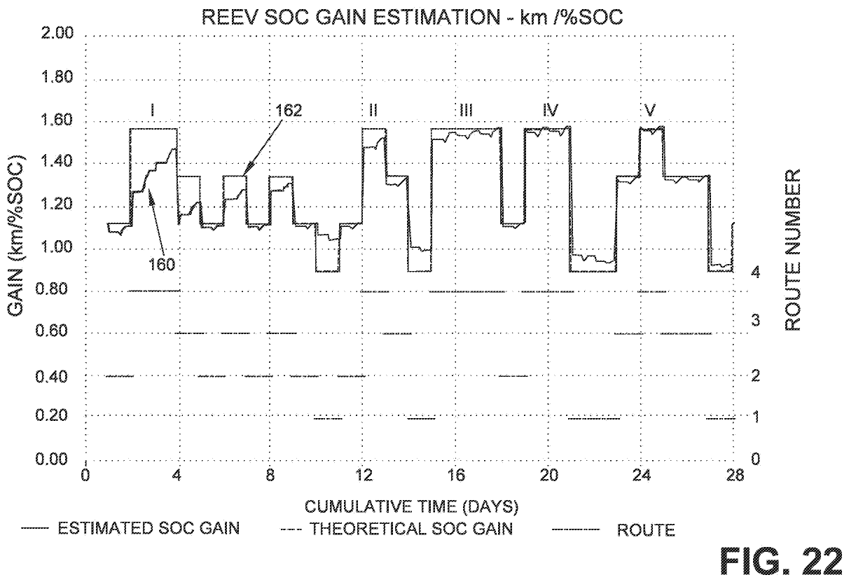

Referring now to the simulation results of FIG. 22, after the vehicle samples a route, the estimated SOC gain curve 160 tracks the theoretical SOC gain curve 162 closer the next time the vehicles runs that route, and as further runs are repeated for the route, the estimated SOC gain 160 closely tracks the theoretical SOC gain 162. For example, as the vehicle in continually ran route 4, the estimated SOC gain 160 closely tracked the theoretical SOC gain 162 for the subsequent runs. That is, the estimated SOC gain 160 for regions II, III, IV, and V more closely track the theoretical SOC gain 162 as compared to region I. This is due to the use of previously stored gain factor estimates associated with route 4.

### 4. Battery Failure Accommodation

Many battery electric vehicles (BEV) and range extended electric vehicles (REEV) have more than one battery to power the vehicle. During operation of these vehicles, it may be possible for one or more batteries to fail and be taken offline. Such an event may skew the calculated values of average SOC gain and thereby skew the vehicle range estimate/prediction.

In such instances, a one-time adjustment factor is applied according to Equation 1 shown below.

$$\\ \begin{matrix}Average SOC Gain = {ASG}_{z - 1} \times ( \frac{NoB}{{NoB}_{z - 1}} ) & Equation 1\end{matrix}$$

where ASG_{z-1} is average SOC gain from the accumulation of previous sampling periods, NoB is the current number of batteries, and NoB_{z-1} is the number of batteries from the previous sampling period.

Also, if a previously failed battery is brought back online, Equation 1 shown above can be used to adjust the average SOC gain.

### 5. Conventional Vehicles and Other Estimation Domains

As mentioned earlier, it is within the scope of the present disclosure that the method described herein can be applied to other vehicle types, such as conventional gasoline, diesel, or natural gas-powered vehicles. In particular, the method described for BEV applications (i.e., a single energy source) could be applied to any vehicle with a single energy source and is not limited to electric vehicle applications. For example, the change in SOC used in Equation 1 of the BEV method could be a fuel consumption parameter for that particular vehicle type. Similarly, one could set the assumed SOC distance in Equation 4 of the BEV method and then execute Equations 5-7 of the BEV method.

In addition, the methods disclosed herein provide estimates in terms of distance. However, it is within the scope of the present disclosure that the methods disclosed herein can be applied in other estimation domains, such as operating time. For example, in many off-road applications (e.g., wheel-loaders, back-hoes, etc.), the vehicle does not move any distance, but rather remains stationary and performs its duties in a single location. In these off-road applications, predicting remaining operating time can be relevant information for operators. The methods discussed herein are applicable in these applications if all references to “distance” were replaced with references to “time.” In this embodiment, the final output would represent the remaining operating time until stored energy in the vehicle is depleted. More particularly, in the equations of the BEV and REEV methods, “distance” or “distance travelled” is replaced with “time,” and the other parameters are redefined accordingly. Also, gain parameters will represent minutes of operation per % SOC or per unit of engine fuel.

While the invention has been described by reference to various specific embodiments it should be understood that numerous changes may be made within the spirit and scope of the inventive concepts described, accordingly, it is intended that the invention not be limited to the described embodiments but will have full scope defined by the language of the following claims.

What is claimed is:

1. A system for estimating a range of a vehicle, the system comprising:
a vehicle including a powertrain, the powertrain including an engine and an electric motor;
a user interface;
a processor in communication with the vehicle and the user interface; and
a memory in communication with the processor;
wherein the processor is configured to:
receive a first set of indications from the vehicle corresponding with a beginning and an ending of a first state of charge sampling period;
provide a weighted average state of charge gain according to a first set of data received from a first set of vehicle subsystems during the first state of charge sampling period and a first cumulative total vehicle distance travelled during a first accumulation of previous sampling periods received from the memory;
receive a second set of indications from the vehicle corresponding with a beginning and an ending of a fuel sampling period;
provide a weighted average fuel gain according to a second set of data received from a second set of vehicle subsystems during the fuel sampling period and a second cumulative total vehicle distance travelled during a second accumulation of previous sampling periods received from the memory;
provide a current vehicle range using at least one of the weighted average state of charge gain and the weighted average fuel gain; and
transmit the current vehicle range to the user interface.

2. The system of claim 1, wherein the first set of data includes a change in a state of charge of an electrical energy storage coupled to the electric motor.

3. The system of claim 1, wherein the second set of data includes an amount of fuel burned by the engine.

4. The system of claim 3, wherein the second set of data includes a change in a state of charge of an electrical energy storage coupled to the electric motor.

5. The system of claim 4, wherein the processor is further configured to:
provide an assumed state of charge distance, wherein the assumed state of charge distance corresponds with a first portion of a vehicle distance travelled during the fuel sampling period which is attributed to the change in the state of charge of the electrical energy storage during the fuel sampling period; and
provide an assumed fuel distance, wherein the assumed fuel distance corresponds with a second portion of the vehicle distance travelled during the fuel sampling period which is attributed to the amount of fuel burned during the fuel sampling period.

6. The system of claim 3, wherein the processor receives the second set of data from a sensor configured to monitor a level of a fuel tank coupled to the engine.

7. The system of claim 1, wherein:
the first set of data includes a vehicle distance travelled during the first state of charge sampling period; and
the second set of data includes a vehicle distance travelled during the second state of charge sampling period.

8. The system of claim 7, wherein the second cumulative total vehicle distance travelled during the second accumulation of previous sampling periods includes the first cumulative total vehicle distance travelled during the first accumulation of previous sampling periods and the vehicle distance travelled during the first state of charge sampling period.

9. The system of claim 1, wherein the processor is further configured to receive a third set of indications from the vehicle corresponding with a beginning and an ending of a second state of charge sampling period.

10. The system of claim 1, wherein the ending of the first state of charge sampling period of the first set of indications is simultaneous with the beginning of the fuel sampling period of the second set of indications.

11. A method of estimating a range of a vehicle, the method comprising:
receiving, with a processor, an indication of a beginning of a first state of charge sampling period;
receiving, with the processor, an indication of an end of the first state of charge sampling period;
simultaneously with receiving the indication of the end of the first state of charge sampling period:
receiving, with the processor, an indication of a beginning of a fuel sampling period; and
providing a weighted average state of charge gain by processing a first set of data from a first plurality of vehicle systems received during the first state of charge sampling system and a first cumulative total vehicle distance travelled from a first accumulation of previous sampling periods;
receiving, with the processor, an indication of an end of the fuel sampling period;
simultaneously with receiving the indication of the end of the fuel sampling period, providing a weighted average fuel gain based on a second set of data from a second plurality of vehicle systems received during the fuel sampling period and a second cumulative total vehicle distance travelled from a second accumulation of previous sampling periods;
providing, with the processor, a current vehicle range using at least one of the weighted average state of charge gain and the weighted average fuel gain; and
notifying a vehicle operator of the current vehicle range.

12. The method of claim 11, wherein the first set of data includes a change in state of charge of a battery occurring during the first state of charge sampling period and a vehicle distance travelled during the first state of charge sampling period.

13. The method of claim 12, wherein providing a weighted average state of charge gain further includes processing an instantaneous state of charge gain, the vehicle distance travelled during the first state of charge sampling period, and an average state of charge gain from the first accumulation of previous sampling periods

14. The method of claim 11, wherein the second set of data includes a change in state of charge of a battery occurring during the first fuel sampling period, a change in fuel amount occurring during the first fuel sampling period, and a vehicle distance travelled during the first fuel sampling period.

15. Th method of claim 14, wherein providing a weighted average state of charge gain further includes processing an instantaneous fuel gain, the vehicle distance travelled during the first fuel sampling period, and an average fuel gain from the second accumulation of previous sampling periods.

16. The method of claim 11, wherein the second plurality of vehicle systems includes a range extender.

17. The method of claim 11, wherein the processor receives indication of the beginning of either the first state of charge sampling period or the first fuel sampling period triggered by at least one of: an ending of another sampling period; a system power-up established by manipulation of a vehicle key-switch; operation of a range extender; and a battery charging event.

18. The method of claim 11, wherein the processor receives indication of the ending of either the first state of charge sampling period or the first fuel sampling period triggered by one of a predetermined time threshold and a predetermined distance threshold.

19. The method of claim 11, further comprising:
simultaneously with receiving the indication of the end of the first fuel sampling period, receiving, with the processor, an indication of a beginning of a second state of charge sampling period.

20. A system for estimating a range of a vehicle, the system comprising:
a user interface;
a processor in communication with the vehicle and the user interface; and
a memory in communication with the processor;
wherein the processor is configured to:
receive a first set of data including a change in a state of charge of an electrical energy storage of the vehicle over at least one of a first vehicle distance and a second vehicle distance;
receive a second set of data including an amount of fuel burned over the second vehicle distance;
provide a current vehicle range using at least one of:
a weighted average state of charge gain including the first set of data and a first cumulative vehicle distance travelled received from the memory; and
a weighted average fuel gain including the second set of data and a second cumulative vehicle distance travelled received from the memory; and
transmit the current vehicle range to the user interface.
